(19) United States
(12) Patent Application Publication
(10) Pub. No.: US 2026/0190702 A1
(43) Pub. Date: Jul. 2, 2026

(54) Display Device

(71) Applicant: LG Display Co., Ltd., Seoul (KR)

(72) Inventors: Seonghwan Woo, Paju-si (KR); DongHun Jung, Paju-si (KR)

(21) Appl. No.: 19/360,820

(22) Filed: Oct. 16, 2025

(30) Foreign Application Priority Data
Dec. 26, 2024 (KR) 10-2024-0196863

(51) Int. Cl. H10K 59/131; H10K 59/122; H10K 77/10; H10K 102/00

(52) U.S. Cl. CPC H10K 59/131; H10K 59/122; H10K 77/111; H10K 2102/351

(57) ABSTRACT

A display device includes a substrate including an active area, a first non-active area surrounding the active area, a bending area extending from the first non-active area, and a second non-active area extending from the bending area; a first planarization layer extending from the active area to be disposed in the first non-active area, the bending area, and the second non-active area of the substrate; link lines on the first planarization layer in the first non-active area, the bending area, and the second non-active area; and a second planarization layer on the link lines in the first non-active area, the bending area, and the second non-active area. The link lines are disposed to be closer to the substrate in a center portion of the bending area than in a boundary of the first non-active area or the second non-active area and the bending area on a cross-section.

### CROSS-REFERENCE TO RELATED APPLICATIONS

This application claims the priority of Republic of Korea Patent Application No. 10-2024-0196863 filed on December 26, 2024, in the Korean Intellectual Property Office, the disclosure of which is incorporated herein by reference.

### BACKGROUND

### Field

The present disclosure relates to a display device, and more particularly, to a display device which is capable of minimizing cracks generated in a bending area.

### DESCRIPTION OF THE RELATED ART

As it enters the information era, a field of a display device which visually expresses electrical information signals has been rapidly developed and studies are continued to improve performances of various display devicees, such as a thin-thickness, a light weight, and low power consumption.

A representative display device may include a liquid crystal display device (LCD), a field emission display device (FED), an electro-wetting display device (EWD), and an organic light emitting display device (OLED).

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, and a contrast ratio (CR), it is expected to be utilized in various fields.

### SUMMARY

An object to be achieved by the present disclosure is to provide a display device which minimizes a damage of a link line due to a tensile stress in a bending area.

Another object to be achieved by the present disclosure is to provide a display device which minimizes cracks generated in a bending area.

Still another object to be achieved by the present disclosure is to provide a low power display device in which a lifespan is improved by improving the reliability of the display device to reduce power consumption.

Objects of the present disclosure are not limited to the above-mentioned objects, and other objects, which are not mentioned above, can be clearly understood by those skilled in the art from the following descriptions.

According to an aspect of the present disclosure, a display device includes a substrate including an active area, a first non-active area surrounding the active area, a bending area extending from the first non-active area, and a second non-active area extending from the bending area; a first planarization layer extending from the active area to be disposed in the first non-active area, the bending area, and the second non-active area of the substrate; a plurality of link lines on the first planarization layer in the first non-active area, the bending area, and the second non-active area; and a second planarization layer on the plurality of link lines in the first non-active area, the bending area, and the second non-active area, and the plurality of link lines is disposed to be closer to the substrate in a center portion of the bending area than in a boundary of the first non-active area or the second non-active area and the bending area on a cross-section.

According to another aspect of the present disclosure, a display device includes. a substrate including an active area, a first non-active area surrounding the active area, a bending area extending from the first non-active area, and a second non-active area extending from the bending area; a first planarization layer on the substrate to be thin as it is close to the center portion of the bending area from the first non-active area and to be thick as it is close to the second non-active area from the center portion of the bending area, in the bending area; a plurality of link lines on the first planarization layer in the bending area to be closest to the substrate in the center portion of the bending area in the bending area; and a second planarization layer on the plurality of link lines in the bending area.

Other detailed matters of the exemplary embodiments are included in the detailed description and the drawings.

In the display device of the present disclosure, a damage of the link line due to the tensile stress during the bending is minimized.

In the display device of the present disclosure, a crack generated in the bending area is minimized to improve the reliability of the display device.

In the display device according to the present disclosure, a crack generated in the bending area is minimized to improve the reliability and the lifespan of the display device, thereby implementing a low power display device with reduced power consumption.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of a display device according to an exemplary embodiment of the present disclosure;

FIG. 2 is a cross-sectional view of one sub pixel of a display device according to an exemplary embodiment of the present disclosure;

FIG. 3 is a cross-sectional view illustrating a bent state of a display device according to an exemplary embodiment of the present disclosure;

FIG. 4 is a cross-sectional view taken along IV-IV' of FIG. 1; and

FIG. 5 is a cross-sectional view of a display device according to another exemplary embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

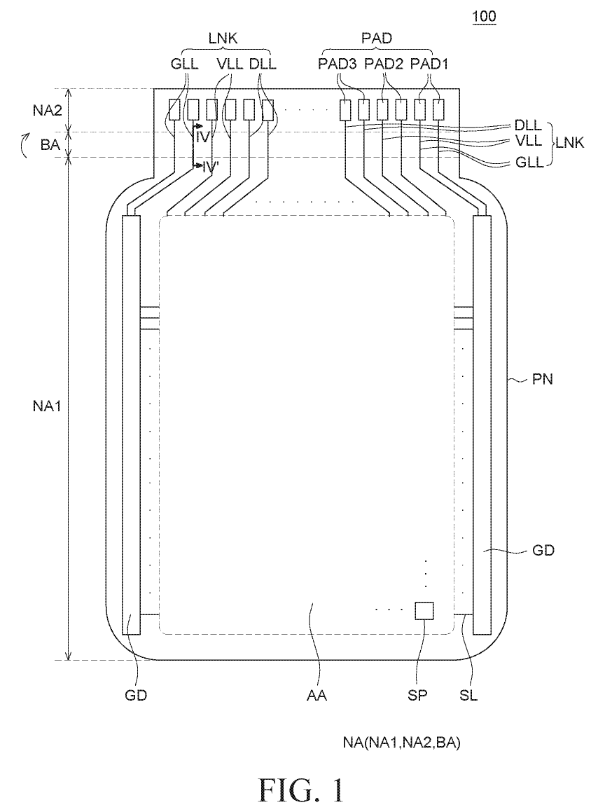

FIG. 1 is a schematic plan view of a display device according to an exemplary embodiment of the present disclosure. In FIG. 1, for the convenience of description, among various components of the display device 100, only a display panel PN, a plurality of pads PAD, a plurality of link lines LNK, a plurality of scan lines SL, and a gate driver GD are illustrated.

Referring to FIG. 1, the display device 100 according to the present disclosure includes a display panel PN, a plurality of pads PAD, a plurality of link lines LNK, a plurality of scan lines SL, and a gate driver GD.

The display panel PN is a panel for displaying images to a user. In the display panel PN, a light emitting diode which displays images, a driving element which drives the light emitting diode, and wiring lines which transmit various signals to the light emitting diode and the driving element may be disposed. Therefore, the display panel PN may include a substrate for supporting various components of the display device 100.

The light emitting diode may be defined in different manners depending on the type of the display panel PN. For example, when the display panel PN is an organic light emitting display panel PN, the light emitting diode may be an organic light emitting diode which includes an anode, an organic emission layer, and a cathode. For example, when the display panel PN is a liquid crystal display panel, the light emitting diode may be a liquid crystal display element. Hereinafter, even though the display panel PN is assumed as an organic light emitting display panel, the display panel PN is not limited to the organic light emitting display panel.

The display panel PN may include an active area AA and a non-active area NA.

The active area AA is an area where images are displayed in the display panel PN. In the active area AA, a plurality of sub pixels SP which configures a plurality of pixels and a driving circuit for driving the plurality of sub pixels SP may be disposed.

The plurality of sub pixels SP is minimum units which configure the active area AA and a light emitting diode may be disposed in each of the plurality of sub pixels SP. For example, an organic light emitting diode which includes an anode, an organic emission layer, and a cathode may be disposed in each of the plurality of sub pixels SP, but it is not limited thereto. Further, the driving circuit for driving the plurality of sub pixels SP may include a driving element and a wiring line. For example, the driving circuit may be configured by a thin film transistor, a storage capacitor, a gate line, and a data line, but is not limited thereto.

The non-active area NA is an area where no image is displayed. The non-active area NA may refer to an outer peripheral portion of the display panel PN which surrounds the active area AA. In the non-active area NA, various wiring lines and circuits for driving the organic light emitting diode of the active area AA are disposed. For example, in the non-active area, the gate driver GD, a data driver, a plurality of link lines LNK, and a plurality of pads PAD may be disposed. A non-active area NA in which an image is not displayed may be a bezel area, but exemplary embodiments of the present disclosure are not limited thereto.

The non-display area NA includes a first non-display area NA1, a bending area BA, and a second non-display area NA2.

The first non-active area NA1 is an area which surrounds the active area AA and extends from the active area AA. The bending area BA may extend from one side of the first non-display area NA1 and may be bent in a direction denoted by an arrow illustrated in FIG. 1. The second non-active area NA2 is an area which extends from the bending area BA to be disposed below the active area AA. In the meantime, like the display panel PN, the substrate may include the active area AA, the first non-active area NA1 which surrounds the active area AA, a bending area BA extending from the first non-active area NA1, and a second non-active area NA2 extending from the bending area BA.

The first non-active area NA1 is an area which surrounds the bending area BA and the active area AA and the plurality of link lines LNK, such as the gate link line GLL, the power link line VLL, and the data link line DLL, and a gate driver GD may be disposed. That is, it serves to transmit a signal transmitted from the plurality of pads PAD to the active area AA. When the display panel PN includes heterogeneous corner areas, the first non-active area NA1 may have a shape corresponding to the shape of the display panel PN and the active area AA.

The gate driver GD supplies a plurality of scan signals to a plurality of scan lines SL according to a plurality of gate control signals supplied from the timing controller. Even though in FIG. 1, it is illustrated that two gate drivers GD are disposed to be spaced apart from each other on both sides of the display panel PN, the number of the gate drivers GD and the placement thereof are not limited thereto.

In the second non-active area NA2, a plurality of pads PAD may be disposed. The plurality of pads PAD includes pads which are connected to various link lines and a flexible film or a printed circuit board.

The plurality of pads PAD may include a plurality of first pads PAD1, a plurality of second pads PAD2, and a plurality of third pads PAD3. The plurality of first pads PAD1 is located on both sides of the display panel PN in the second non-active area NA2 and the plurality of second pads PAD2 is disposed in the middle of the display panel PN in the second non-active area NA2. For example, the plurality of second pads PAD2 may be located between the plurality of first pads PAD1 and the plurality of third pads PAD3 may be located between the plurality of second pads PAD2.

The plurality of first pads PAD1 is electrically connected to a plurality of gate link lines GLL, among the plurality of link lines LNK. The plurality of gate link lines GLL may be link lines which are connected to the gate driver GD.

The plurality of second pads PAD2 is electrically connected to a plurality of power link lines VLL, among the plurality of link lines LNK. The plurality of power link lines VLL may be link lines which are connected to the power line disposed in the active area AA.

The plurality of third pads PAD3 is electrically connected to a plurality of data link lines DLL, among the plurality of link lines LNK. The plurality of data link lines DLL may be link lines which are connected to the data line disposed in the active area AA.

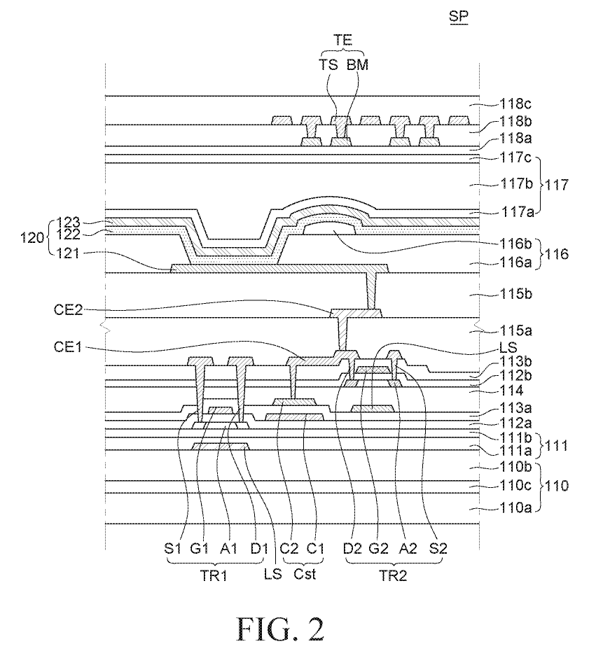

Hereinafter, a cross-sectional structure of the active area AA of the display device 100 will be described in more detail with reference to FIG. 2 together.

FIG. 2 is a cross-sectional view illustrating one sub pixel of a display device according to an exemplary embodiment of the present disclosure.

Referring to FIG. 2, the display device 100 according to an exemplary embodiment of the present disclosure may include a substrate 110, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a first connection electrode CE1, a light shielding layer LS, a first planarization layer 115a, a second planarization layer 115b, a second connection electrode CE2, a bank unit 116, a light emitting diode 120, an encapsulation unit 117, and a touch sensing unit.

The substrate 110 serves to support and protect components of the display device 100 disposed thereabove.

The substrate 110 is a component for supporting various components included in the display device 100 and may be formed of an insulating material. The substrate 110 may include a first substrate 110a, a second substrate 110b, and an insulating film 110c. The insulating film 110c may be disposed between the first substrate 110a and the second substrate 110b. As described above, the substrate 110 is configured by the first substrate 110a, the second substrate 110b, and the insulating film 110c to suppress the moisture permeation. For example, the first substrate 110a and the second substrate 110b may be polyimide (PI) substrates and the interlayer insulating film 110c may be formed of a single layer of silicon nitride (SiNx) or silicon oxide (SiOx) or multiple layers thereof.

The insulating film 110c may include at least one patterning area. For example, the insulating film 110c may include an opening portion in the bending area BA.

The first buffer layer 111 is disposed on the substrate 110. The first buffer layer 111 is disposed below the first transistor TR1 to delay diffusion of moisture and oxygen which has permeated into the substrate 110, to the first transistor TR1.

The first buffer layer 111 may include a multi-buffer layer 111a and an active buffer layer 111b. The first buffer layer 111 may be formed by multiple layers including the multi-buffer layer 111a and the active buffer layer 111b. Therefore, even though the first buffer layer 111 may be referred to as a multi-buffer layer, the first buffer layer 111 may be formed by a single layer or may be formed of a plurality of layers, other than two layers, but is not limited thereto.

For example, the multi-buffer layer 111a may be formed by a single layer of any one of amorphous silicon (a-Si), silicon nitride (SiNx), and silicon oxide (SiOx) or multiple layers thereof, but is not limited thereto.

For example, the active buffer layer 111b may be formed by a single layer of any one of amorphous silicon (a-Si), silicon nitride (SiNx), and silicon oxide (SiOx) or multiple layers thereof, but is not limited thereto.

The first thin film transistor TR1 may be disposed on the first buffer layer 111. The first thin film transistor TR1 may include a first active layer A1, a first gate electrode G1, a first source electrode S1, and a first drain electrode D1. Here, depending on the design of the pixel circuit, the first source electrode S1 may serve as a first drain electrode and the first drain electrode D1 may serve as a first source electrode.

The first active layer A1 may be disposed on the first buffer layer 111 so as to overlap the light shielding layer LS. The first active layer A1 may include amorphous silicon or polycrystalline silicon.

For example, the first active layer A1 may include a low-temperature polycrystalline silicon LTPS. For example, the polycrystalline silicon material has a high mobility (100 cm²/Vs or higher) so that energy power consumption is low and reliability is excellent. Therefore, the polycrystalline silicon material may be applied to a gate driver for driving elements which drive thin film transistors for a display element and/or a multiplexer (MUX) and also applied as an active layer A1 of a driving thin film transistor of the display device 100 according to the exemplary embodiment, but is not limited thereto.

For example, the polycrystalline silicon material may also be applied as the active layer A2 of the switching thin film transistor according to the characteristic of the display device 100. An amorphous silicon (a-Si) material is deposited on the first buffer layer 111 and a dehydrogenation process and a crystallization process are performed to form polycrystalline silicon and the polycrystalline silicon is patterned to form the first active layer A1. Here, the first active layer A1 may include a first channel region in which a channel is formed when the first thin film transistor TR1 is driven, and a first source region and a first drain region on both sides of the first channel region. The first source region refers to a part of the first active layer A1 which is connected to the first source electrode S1 and the first drain region refers to a part of the first active layer A1 which is connected to the first drain electrode D1. For example, the first source region and the first drain region may be configured by ion-doping (impurity doping) of the first active layer A1. The first source region and the first drain region may be generated by doping ions into the polycrystalline silicon material and the first channel region may refer to a part in which the ions are not doped, but the polycrystalline silicon material remains.

The first gate insulating layer 112a may be disposed on the first active layer A1. The first gate insulating layer 112a may be configured by a single layer of silicon nitride (SiNx) or silicon oxide (SiOx) or a multi-layer thereof. In the first gate insulating layer 112a, a contact hole through which the first source electrode S1 and the first drain electrode D1 of the first thin film transistor TR1 are connected to the first source region and the first drain region of the first active layer A1 of the first thin film transistor TR1, respectively, may be formed.

The first gate electrode G1 of the first thin film transistor TR1 and a first capacitor electrode C1 of the storage capacitor Cst may be disposed on the first gate insulating layer 112a.

At this time, the first gate electrode G1 and the first capacitor electrode C1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 may be formed on the first gate insulating layer 112a so as to overlap the first channel region of the first active layer A1 of the first thin film transistor TR1.

The first capacitor electrode C1 may be omitted based on a driving characteristic of the display device 100 and a structure and a type of the thin film transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed above the first gate insulating layer 112a, the first gate electrode G1, and the first capacitor electrode C1. The first interlayer insulating layer 113a may be configured by a single layer of silicon nitride SiNx or silicon oxide SiOx or a multi-layer thereof. In the first interlayer insulating layer 113a, a contact hole for exposing the first source region and the first drain region of the first active layer A1 of the first thin film transistor TR1 may be formed.

A second capacitor electrode C2 of the storage capacitor Cst may be disposed on the first interlayer insulating layer 113a. The second capacitor electrode C2 may be formed by a single layer or multiple layers formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display device 100 and a structure and a type of the thin film transistor.

The second buffer layer 114 may be disposed on the first interlayer insulating layer 113a and the second capacitor electrode C2. The second buffer layer 114 may be configured by a single layer of silicon nitride (SiNx) or silicon oxide (SiOx) or a multi-layer thereof. A contact hole for exposing the first source region and the first drain region of the first active layer A1 of the first thin film transistor TR1 may be formed in the second buffer layer 114. Further, in the second buffer layer 114, a contact hole for exposing the second capacitor electrode C2 of the storage capacitor Cst may be formed.

The second buffer layer 114 may be formed by multiple layers, but is not limited thereto.

The second active layer A2 of the second thin film transistor TR2 may be disposed on the second buffer layer 114. Here, the second thin film transistor TR2 may include a second active layer A2, a second gate insulating layer 112b, a second gate electrode G2, a second source electrode S2, and a second drain electrode D2. Here, depending on the design of the pixel circuit, the second source electrode S2 may serve as a drain electrode and the second drain electrode D2 may serve as a source electrode.

Further, the second active layer A2 may include a second channel region in which a channel is formed when the second thin film transistor TR2 is driven, and a second source region and a second drain region on both sides of the second channel region. The second source region may refer to a part of the second active layer A2 which is connected to the second source electrode S2 and the second drain region may refer to a part of the second active layer A2 which is connected to the second drain electrode D2.

The second active layer A2 may be formed of an oxide semiconductor. The oxide semiconductor material has a larger band gap than a silicon material so that electrons cannot jump over the band gap in an off state. Therefore, the oxide semiconductor material has a low off-current. Therefore, the thin film transistor including an active layer which is formed of an oxide semiconductor may be suitable for a switching thin film transistor which maintains on-time to be short and off-time to be long, but is not limited thereto. Depending on the characteristic of the display device 100, it may be applied as a driving thin film transistor. Further, due to the small off-current, a magnitude of an auxiliary capacitance may be reduced so that the oxide semiconductor may be appropriate for a high resolution display element. For example, the second active layer A2 may be formed of metal oxide and for example, may be formed of various metal oxides such as indium-gallium-zinc-oxide (IGZO). Here, the description was made under assumption that the second active layer 2 of the second thin film transistor TR2 was configured by IGZO, among various metal oxides, but it is not limited thereto. Therefore, the second active layer may be formed of another metal oxide such as indium-zinc-oxide (IZO), indium-gallium-tin-oxide (IGTO), or indium-gallium-oxide (IGO), rather than IGZO.

The second active layer A2 may be formed by depositing the metal oxide on the second buffer layer 114, performing a heat treatment for stabilization, and then patterning the metal oxide.

The second gate insulating layer 112b may be disposed on the entire substrate 110 including the second active layer A2. For example, the second gate insulating layer 112b may be configured by a single layer of silicon nitride SiNx or silicon oxide SiOx or a multi-layer thereof.

The second gate electrode G2 may be disposed on the second gate insulating layer 112b.

The second gate electrode G2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material may be used.

The second interlayer insulating layer 113b may be disposed on the second gate insulating layer 112b and the second gate electrode G2. A contact hole for exposing the first active layer A1 of the first thin film transistor TR1 and the second active layer A2 of the second thin film transistor TR2 may be formed in the second interlayer insulating layer 113b. For example, a contact hole for exposing the first source region and the first drain region of the first active layer A1 of the first thin film transistor TR1 may be formed in the second interlayer insulating layer 113b. A contact hole for exposing the second source region and the second drain region of the second active layer A2 of the second thin film transistor TR2 may be formed in the second interlayer insulating layer 113b.

The second interlayer insulating layer 113b may be configured as a single layer of silicon nitride SiNx or silicon oxide SiOx or a multi-layer thereof.

A first connection electrode CE1, the first source electrode S1 and the first drain electrode D1 of the first thin film transistor TR1 and the second source electrode S2 and the second drain electrode D2 of the second thin film transistor TR2 may be disposed on the second interlayer insulating layer 113b.

The first connection electrode CE1 may be electrically connected to the second drain electrode D2 of the second thin film transistor TR2. Further, the first connection electrode CE1 may be electrically connected to the second capacitor electrode C2 of the storage capacitor Cst through the contact holes formed in the second buffer layer 114 and the second interlayer insulating layer 113b. That is, the first connection electrode CE1 may serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR1 may be connected to the first active layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 may be connected to the second active layer A2 through the contact hole formed in the second interlayer insulating layer 113b.

The first connection electrode CE1, the first source electrode S1 and the first drain electrode D1 of the first thin film transistor TR1 and the second source electrode S2 and the second drain electrode D2 of the second thin film transistor TR2 may be formed of the same material by the same process.

For example, the first connection electrode CE1, the first source electrode S1 and the first drain electrode D1 of the first thin film transistor TR1 and the second source electrode S2 and the second drain electrode D2 of the second thin film transistor TR2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the first connection electrode CE1, the first source electrode S1 and the first drain electrode D1 of the first thin film transistor TR1 and the second source electrode S2 and the second drain electrode D2 of the second thin film transistor TR2 may be formed of a triple layered structure of titanium (Ti)/aluminum (Al)/titanium (Ti), but are not limited thereto.

The first connection electrode CE1 may be integrally formed to be connected to the second drain electrode D2 of the second thin film transistor TR2, but is not limited thereto.

In the first thin film transistor TR1 and the second thin film transistor TR2, light shielding layers LS are disposed below the first active layer A1 and the second active layer A2, respectively. The light shielding layer LS may be disposed so as to overlap the first active layer A1 between the substrate 110 and the first buffer layer 111 and be disposed so as to overlap the second active layer A2 between the first interlayer insulating layer 113a and the second buffer layer 114. Therefore, the light shielding layer LS may be insulated from the first active layer A1 and the second active layer A2.

The light shielding layer LS may be formed of a metal material having low light transmittance and reflect light which is incident onto the first active layer A1 and the second active layer A2, below the first active layer A1 and the second active layer A2. The light shielding layer LS may shield light which is incident onto the first active layer A1 and the second active layer A2 and protect the first active layer A1 and the second active layer A2.

For example, the light shielding layer LS may be referred to as a bottom shield metal (BSM), but is not limited thereto. Specifically, the light shielding layer LS may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The first planarization layer 115a may be disposed above the first connection electrode CE1, the first source electrode S1 and the first drain electrode D1 of the first thin film transistor TR1 and the second source electrode S2 and the second drain electrode D2 of the second thin film transistor TR2, and the second interlayer insulating layer 113b.

The first planarization layer 115a may be an organic layer which planarizes and protects upper portions of the first thin film transistor TR1 and the second thin film transistor TR2. For example, the first planarization layer 115a may be formed of an organic material such as acryl resin, epoxy resin, phenolic resin, polyamide resin, or polyimide resin.

The second connection electrode CE2 may be disposed on the first planarization layer 115a. The second connection electrode CE2 may be connected to the second drain electrode D2 of the second thin film transistor TR2 through the contact hole of the first planarization layer 115a. The second connection electrode CE2 may serve to electrically connect the second thin film transistor TR2 and the anode 121 with each other. The second connection electrode CE2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second planarization layer 115b may be disposed above the second connection electrode CE2 and the first planarization layer 115a. For example, the second planarization layer 115b may be formed of an organic material, such as acryl resin, epoxy resin, phenolic resin, polyamide resin, or polyimide resin.

The light emitting diode 120 may be disposed on the second planarization layer 115b. That is, the light emitting diode 120 may be formed by the anode 121, the emission layer 122, and the cathode 123.

The anode 121 may be disposed on the second planarization layer 115b. At this time, the anode 121 may be electrically connected to the second connection electrode CE2 through the contact hole provided in the second planarization layer 115b. The anode 121 may be formed of a metallic material.

When the display device 100 is a top emission type in which light emitted from the light emitting diode 120 is emitted above the substrate 110 in which the light emitting diode 120 is disposed, the anode 121 may further include a transparent conductive layer and a reflective layer on the transparent conductor layer. The transparent conductive layer may be formed of transparent conductive oxide, such as ITO or IZO and the reflective layer may be formed of silver (Ag), aluminum (Al), gold (Au), molybdenum (Mo), tungsten (W), chrome (Cr), or an alloy thereof.

The bank unit 116 may be disposed on the anode 121. The bank unit 116 includes a bank layer 116a and a spacer 116b.

The bank layer 116a may be disposed while covering an end of the anode 121. A part of the bank layer 116a corresponding to an emission area of the sub pixel SP may be open. A part of the anode 121 may be exposed through the open part of the bank layer 116a (hereinafter, referred to as an open area). At this time, the bank layer 116a may be formed of an inorganic insulating material, such as silicon nitride (SiNx) or silicon oxide (SiOx), or an organic insulating material, such as benzocyclobutene resin, acrylic resin or imide resin, but is not limited thereto.

The spacer 116b may be disposed on the bank layer 116a. The spacer 116b serves to maintain a predetermined gap so that the mask is not in contact with the substrate during a manufacturing process of the emission layer 122 formed of an organic material. For example, the spacer 116b may be formed of an inorganic insulating material, such as silicon nitride (SiNx) or silicon oxide (SiOx), or an organic insulating material, such as benzocyclobutene resin, acrylic resin or imide resin, but is not limited thereto.

The emission layer 122 may be disposed in the open area of the bank layer 116a and on the front surface thereof. Therefore, the emission layer 122 may be disposed on the anode 121 exposed through the open area of the bank layer 116a.

The emission layer 122 may include a plurality of organic material layers. For example, the emission layer 122 may include an organic material layer such as a hole injection layer, a hole transport layer, an electron transport layer, and an electron injection layer. In the meantime, when the emission layer 122 emits white light, light emitted from the emission layer 122 may be converted into light with various colors by a plurality of color filters, but is not limited thereto.

The cathode 123 may be disposed on the emission layer 122. The cathode 123 supplies electrons to the emission layer 122 so that the cathode may be formed of a conductive material having a low work function. The cathode 123 may be formed as one layer over the plurality of sub pixels SP. That is, the cathodes 123 of the plurality of sub pixels SP are connected to be integrally formed.

For example, the cathode 123 may be formed of a transparent conductive material such as indium tin oxide (ITO) and indium zinc oxide (IZO) or ytterbium (Yb) alloy and may further include a metal doping layer, but is not limited thereto.

The encapsulation unit 117 may be located on the above-described light emitting diode 120.

The encapsulation unit 117 may have a single layer structure or a multi-layered structure. For example, the encapsulation unit 117 may include a first encapsulation layer 117a, a second encapsulation layer 117b, and a third encapsulation layer 117c.

At this time, the first encapsulation layer 117a and the third encapsulation layer 117c are configured by inorganic layers and the second encapsulation layer 117b may be configured by an organic layer. Among the first encapsulation layer 117a, the second encapsulation layer 117b, and the third encapsulation layer 117c, the second encapsulation layer 117b is the thickest and may serve as a planarization layer.

The first encapsulation layer 117a may be disposed on the cathode 123 and be disposed to be most adjacent to the light emitting diode 120. The first encapsulation layer 117a may be formed of an inorganic insulating material on which low-temperature deposition can be performed. For example, the first encapsulation layer 117a may be configured by silicon nitride (SiNx), silicon oxide (SiOx), silicon oxynitride (SiON), or aluminum oxide (Al₂O₃). The first encapsulation layer 117a is deposited under a low temperature atmosphere so that during the deposition process, the damage of the emission layer 122 including an organic material which is vulnerable to the high temperature atmosphere may be suppressed.

The second encapsulation layer 117b may be formed to have a smaller area than that of the first encapsulation layer 117a. In this case, the second encapsulation layer 117b may be formed to expose both ends of the first encapsulation layer 117a. The second encapsulation layer 117b may serve as a buffer to alleviate stress between the layers due to bending of the display device and to enhance planarization performance.

For example, the second encapsulation layer 117b may be formed of an organic insulating material, such as acrylic resin, epoxy resin, polyimide, polyethylene, or silicon oxy carbon (SiOC). For example, the second encapsulation layer 117b may be formed by an inkjet method, but is not limited thereto.

The third encapsulation layer 117c may be formed above the substrate 110 on which the second encapsulation layer 117b is formed so as to cover upper surfaces and side surfaces of the second encapsulation layer 117b and the first encapsulation layer 117a. At this time, the third encapsulation layer 117c may minimize or block the permeation of external moisture or oxygen into the first encapsulation layer 117a and the second encapsulation layer 117b. For example, the third encapsulation layer 117c may be configured by an inorganic insulating material, such as silicon nitride SiNx, silicon oxide SiOx, silicon oxynitride SiON, or aluminum oxide Al₂O₃.

The touch sensing unit may be disposed on the encapsulation unit 117. The touch sensing unit may include a touch electrode unit TE including a touch sensor metal TS and a bridge metal BM and a touch insulating layer including a touch buffer layer 118a, a touch interlayer insulating layer 118b, and a touch planarization layer 118c.

For example, the touch buffer layer 118a may be disposed on the third encapsulation layer 117c and the touch electrode unit TE may be disposed on the touch buffer layer 118a.

The touch electrode unit TE may include a touch sensor metal TS and a bridge metal BM located on different layers. A touch interlayer insulating layer 118b may be disposed between the touch sensor metal TS and the bridge metal BM.

The touch buffer layer 118a and the touch interlayer insulating layer 118b may be disposed to remove a step of a location where the touch electrode unit TE is disposed and be electrically insulated. Therefore, the touch buffer layer 118a and the touch interlayer insulating layer 118b may be formed of an inorganic material, and for example, may be configured by a single layer or multiple layers of silicon nitride (SiNx) or silicon oxide (SiOx).

A touch planarization layer 118c is disposed on the touch interlayer insulating layer 118b and the touch sensor metal TS. The touch planarization layer 118c may be an organic layer which planarizes and protects an upper portion of the touch interlayer insulating layer 118b. For example, the touch planarization layer 118c may be formed of an organic material such as acryl resin, epoxy resin, phenolic resin, polyamide resin, or polyimide resin. The touch electrode unit TE may be formed as a mesh type.

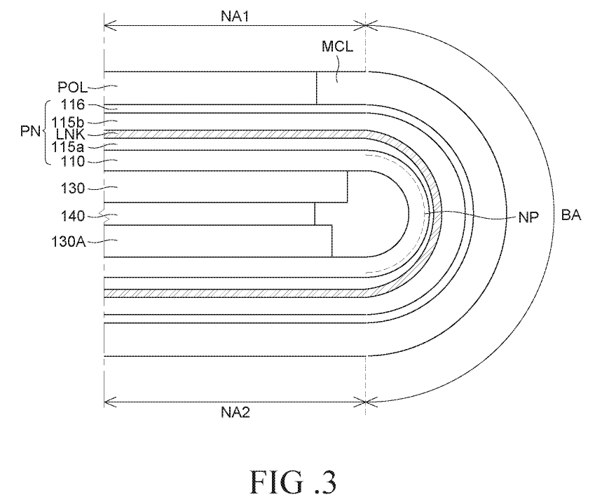

FIG. 3 is a cross-sectional view illustrating a bent state of a display device according to an exemplary embodiment of the present disclosure. In the meantime, in FIG. 3, for the convenience of description, among components of the display device 100, only a substrate 110, a first planarization layer 115a, a plurality of link line LNK, a second planarization layer 115b, and a bank unit 116 of a display panel PN and a polarization plate POL, a micro coating layer MCL, a back plate 130, a cushion tape 140, and an additional back plate 130A are illustrated.

Referring to FIGS. 1 and 3, the display device 100 according to the exemplary embodiment of the present disclosure may include the polarization plate POL and the micro coating layer MCL disposed on the display panel PN and the back plate 130, the cushion tape 140, and the additional back plate 130A disposed below the display panel PN.

Referring to FIG. 3, the polarization plate POL is disposed on the display panel PN. The polarization plate POL is disposed in the active area AA and the first non-active area NA1 of the display panel PN. The polarization plate POL is disposed on the bank unit 116 in the first non-active area NA1. The polarization plate POL selectively transmits light to reduce the reflection of external light which is incident onto the display panel PN. Specifically, the display panel PN includes various metal materials applied to the semiconductor element, the wiring line, and the organic light emitting diode. Therefore, the external light incident onto the display panel PN may be reflected from the metal material so that the visibility of the display device 100 may be reduced due to the reflection of the external light. In contrast, when the polarization plate POL is disposed, the polarization plate POL suppresses the reflection of the external light so that the outdoor visibility of the display device 100 may be increased. However, the polarization plate POL may be omitted depending on an implementation embodiment of the display device 100, but it is not limited thereto.

An adhesive layer may be disposed between the polarization plate POL and the display panel PN. The adhesive layer may bond the polarization plate POL and the display panel PN. Consequently, the adhesive layer may be formed as a transparent adhesive layer to allow an image of the display panel PN to be visible. For example, the adhesive layer may be formed of an optical clear adhesive (OCA) or a pressure sensitive adhesive (PSA), but is not limited thereto.

The back plate 130 is disposed below the display panel PN. The back plate 130 may be disposed so as to support the display panel PN. For example, when the substrate 110 of the display panel PN is formed of a plastic material, such as polyimide, due to the flexible property, a separate component for supporting the substrate may be necessary. Therefore, a support substrate which is formed of glass is disposed below the substrate 110 to perform a manufacturing process of the display device 100 and the support substrate may be separated to be released after completing the manufacturing process. However, a component for supporting the substrate 110 is necessary even after releasing the support substrate, so that a back plate 130 for supporting the substrate 110 may be disposed below the display panel PN.

The back plate 130 may include a plastic material. For example, the back plate 130 may be formed of a plastic thin film formed of polyimide (PI), polyethylene naphthalate (PEN), polyethylene terephthalate (PET), or a combination of the polymers.

A cushion tape 140 is disposed below the back plate 130. The cushion tape 140 may protect the components of the display device 100 from external shocks. That is, the cushion tape 140 is compressed when an external force is applied to absorb shocks. Specifically, the cushion tape 140 may include a plurality of air bubbles and the plurality of air bubbles may effectively absorb the physical shock which is applied to the display device 100. For example, the cushion tape 140 may be formed of acrylic foam, but is not limited thereto.

An additional back plate 130A is disposed below the cushion tape 140 corresponding to the first non-active area NA1.

The additional back plate 130A may supplement the rigidity of the second non-active area NA2 of the display panel PN disposed in the second non-active area NA2. In the meantime, the additional back plate 130A may be disposed so as not to overlap the bending area BA. Therefore, the thicknesses of the configurations disposed in the bending area BA may be minimized and a neutral plane of the bending area BA may be easily controlled to ensure the flexibility of the bending area BA. The additional back plate 130A may be formed of the same material as the back plate 130. For example, the additional back plate 130A may include a plastic material and be formed of a plastic thin film formed of polyimide (PI), polyethylene naphthalate (PEN), polyethylene terephthalate (PET), or a combination of the polymers, but is not limited thereto.

The adhesive layer may be disposed between the display panel PN and the back plate 130, between the back plate 130 and the cushion tape 140, and between the cushion tape 140 and the additional back plate 130A. The adhesive layer may bond the display panel PN, the back plate 130, the cushion tape 140, and the additional plate 130A to each other. For example, the adhesive layer may be formed of an optical clear adhesive (OCA) or a pressure sensitive adhesive (PSA), but is not limited thereto.

The second non-active area NA2 of the display panel PN is disposed below the additional back plate 130A. Further, the adhesive layer is also disposed between the additional plate 130A and the second non-active area NA2 of the display panel PN to bond the additional back plate 130A and the second non-active area NA2 of the display panel PN to each other.

A micro coating layer MCL is disposed on the first non-active area NA1, the second non-active area NA2, and the bending area BA of the display panel PN. Since a tensile stress is applied to a plurality of link lines LNK disposed on the substrate 110 during the bending to cause minute crack, the micro coating layer MCL may be formed by coating a resin in a position to be bent with a small thickness to protect the plurality of link lines LNK. For example, the micro coating layer MCL may be configured by resin or configured by an acrylic material or urethane acrylate, but is not limited thereto.

The plurality of link lines LNK is disposed between the first planarization layer 115a and the second planarization layer 115b on the substrate 110 in the bending area BA. At this time, the plurality of link lines LNK may be disposed on the first planarization layer 115a and be disposed to be the closest to the substrate 110 in a center portion of the bending area BA. That is, the plurality of link lines LNK is disposed to be closer to the substrate 110 in the center portion of the bending area BA than in the boundary of the first non-active area NA1 or the second non-active area NA2 and the bending area BA on the cross-section. For example, the plurality of link lines LNK may be formed on the same layer as the second connection electrode CE2 illustrated in FIG. 2 in the bending area BA.

At this time, a curvature of the plurality of link lines LNK may be smaller in the center portion of the bending area BA than in the boundary of the first non-active area NA1 or the second non-active area NA2 and the bending area BA. That is, in the bending area BA, the closer to the center portion of the bending area BA from the boundary of the first non-active area NA1, the smaller the curvature of the plurality of link lines LNK and the closer to the boundary of the second non-active area NA2 from the center portion of the bending area BA, the larger the curvature of the plurality of link lines. Consequently, the curvature of the plurality of link lines LNK may be smallest in the center portion of the bending area BA with respect to a boundary point of the first non-active area NA1 of the bending area BA and a boundary point of the second non-active area NA2 of the bending area BA.

The closer to the center portion of the bending area BA from the first non-active area NA1 in the bending area BA, the thinner the first planarization layer 115a and the closer to the second non-active area NA2 from the center portion of the bending area BA, the thicker the first planarization layer 115a to be disposed on the substrate 110.

The closer to the center portion of the bending area BA from the first non-active area NA2 in the bending area BA, the thicker the second planarization layer 115b and the closer to the second non-active area NA2 from the center portion of the bending area BA, the thinner the second planarization layer 115b to be disposed on the plurality of link lines LNK.

The bank unit 116 is disposed on the second planarization layer 115b. At this time, the bank unit 116 may be disposed on the second planarization layer 115b to be thicker in the bending area BA than in the first non-active area NA1 or the second non-active area NA2. Therefore, the bank unit 116 may planarize and protect an upper portion of the second planarization layer 115b in the bending area BA.

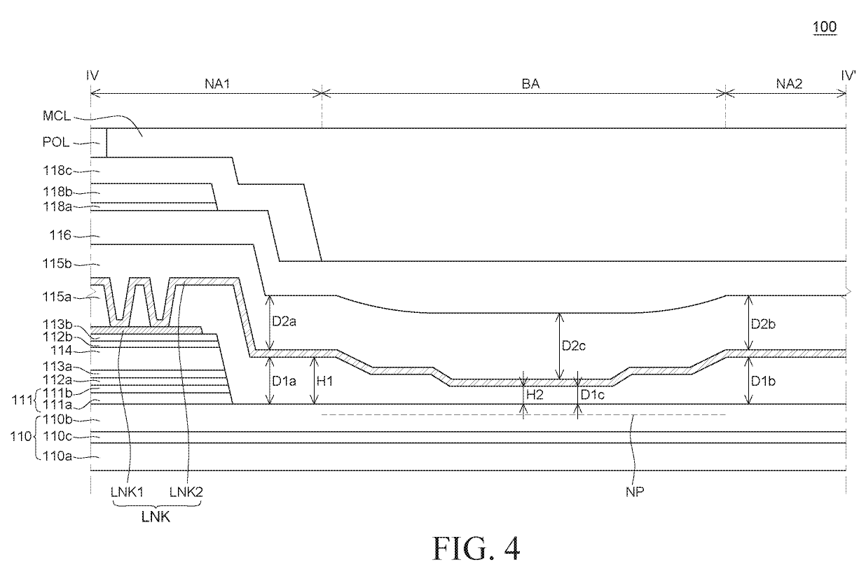

Hereinafter, a cross-sectional structure of the bending area BA of the display device 100 will be described in more detail with reference to FIG. 4 together.

FIG. 4 is a cross-sectional view taken along IV-IV' of FIG. 1 and FIG. 4 is a cross-sectional view illustrating a bending area BA of an unfolded state of the display device 100 according to the exemplary embodiment of the present disclosure. In FIG. 4, among various components of the display device 100, only a substrate 110, a first buffer layer 111, a first gate insulating layer 112a, a first interlayer insulating layer 113a, a second buffer layer 114, a second gate insulating layer 112b, a second interlayer insulating layer 113b, a first planarization layer 115a, a second planarization layer 115b, a plurality of link lines LNK, a bank unit 116, a touch buffer layer 118a, a touch interlayer insulating layer 118b, a touch planarization layer 118c, a polarization plate POL, and a micro coating layer MCL are illustrated.

Referring to FIGS. 2 and 4, in the display device 100 according to the exemplary embodiment of the present disclosure, in the bending area BA extending from the first non-active area NA1 of the display panel PN and the second non-active area NA2, the first planarization layer 115a, the plurality of link lines LNK, the second planarization layer 115b, the bank unit 116, and the micro coating layer MCL are disposed.

In the first non-active area NA1, ends of the first buffer layer 111, the first gate insulating layer 112a, the first interlayer insulating layer 113a, the second buffer layer 114, the second gate insulating layer 112b, and the second interlayer insulating layer 113b are disposed. In the meantime, the first buffer layer 111, the first gate insulating layer 112a, the first interlayer insulating layer 113a, the second buffer layer 114, the second gate insulating layer 112b, and the second interlayer insulating layer 113b are highly likely to be cracked during the bending so that they are not disposed in the bending area BA.

The plurality of link lines LNK includes a first link line LNK1 and a second link line LNK2.

In the first non-active area NA1, the first link line LNK1 is disposed on the second interlayer insulating layer 113b. The first link line LNK1 may be formed of the same material as one of various conductive components formed in the active area AA. For example, the first link line LNK1 may be formed of the same material by the same process as the first connection electrode CE1 on the second interlayer insulating layer 113b. That is, the first link line LNK1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. Further, the second link line LNK2 may be formed by a triple-layered structure of titanium (Ti)/aluminum (Al)/titanium (Ti), but is not limited thereto.

In the first non-active area NA1, the second link line LNK2 is disposed on the first link line LNK1 and the first planarization layer 115a. The second link line LNK2 may be electrically connected to the first link line LNK1 through a contact hole of the first planarization layer 115a.

The second link line LNK2 may be disposed to the second non-active area NA2 along the bending area BA extending from the first non-active area NA1. At this time, a height H1 of the second link line LNK2 from the substrate 110 in the boundary of the first non-active area NA1 and the bending area BA may be higher than a height H2 from the substrate 110 in the center portion of the bending area BA. That is, a height H2 of the second link line LNK2 from the substrate 110 in the center portion of the bending area BA is lower than a height H1 from the substrate 110 in the boundary of the first non-active area NA1 and the bending area BA. Accordingly, in the center portion of the bending area BA, the second link line LNK2 may be disposed to be the closest to the substrate 110.

At this time, a curvature of the plurality of second link lines LNK2 may be smaller in the center portion of the bending area BA than in the boundary of the first non-active area NA1 or the second non-active area NA2 and the bending area BA. That is, the closer to the center portion of the bending area BA from the boundary of the first non-active area NA1, the smaller the curvature of the second link line LNK2 in the bending area BA, and the closer to the boundary of the second non-active area NA2 from the center portion of the bending area BA, the larger the curvature of the second link line. Consequently, the curvature of the second link line LNK2 may be the smallest in the center portion of the bending area BA with respect to a boundary point of the first non-active area NA1 of the bending area BA and a boundary point of the second non-active area NA2. The second link line LNK2 may be formed of the same material as one of various conductive components formed in the active area AA. For example, the second link line LNK2 may be formed of the same material by the same process as the second connection electrode CE2 on the first planarization layer 115a. That is, the second link line LNK2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. Further, the second link line LNK2 may be formed by a triple-layered structure of titanium (Ti)/aluminum (Al)/titanium (Ti), but is not limited thereto.

In the meantime, a neutral plane NP in the bending area BA may be located in the second substrate 110b of the substrate 110. Therefore, the second link lines LNK2 may be disposed to be closer to the neutral plane of the center portion of the bending area BA than the boundary of the first non-active area NA1 or the second non-active area NA2 and the bending area BA.

In the bending area BA, the first planarization layer 115a is disposed on the substrate 110. At this time, the closer to the center portion of the bending area BA from the first non-active area NA1, the smaller the thickness of the first planarization layer 115a and the closer to the second non-active area NA2 from the center portion of the bending area BA, the larger the thickness of the first planarization layer 115a. That is, a thickness D1c of the first planarization layer 115a in the center portion of the bending area BA is smaller than a thickness D1a at an interface of the first non-active area NA1 and the bending area BA and a thickness D1b at an interface of the second non-active area NA2 and the bending area BA. Accordingly, in the center portion of the bending area BA, the second link line LNK2 may be disposed to be the closest to the substrate 110 according to the thickness of the first planarization layer 115a.

Such a first planarization layer 115a may have a step shape on the cross-section. For example, the first planarization layer 115a may form a step shape using a slit shape and/or a half-tone mask. At this time, a steepness of a slope of a concave shape of the first planarization layer 115a may be adjusted according to a slit spacing of the mask and straightness may be adjusted to be gentle using the half-tone mask. For example, the smaller the slit spacing of the mask, the gentler the slope and the larger the slit spacing, the steeper the slope. At this time, a flat surface is formed between slopes using the halftone mask to form a step shape.

In the bending area BA, the second planarization layer 115b is disposed on the second link line LNK2. At this time, the closer to the center portion of the bending area BA from the first non-active area NA1, the larger the thickness of the second planarization layer 115b and the closer to the second non-active area NA2 from the center portion of the bending area BA, the smaller the thickness of the second planarization layer 115b. That is, a thickness D2c of the second planarization layer 115b in the center portion of the bending area BA is larger than a thickness D2a at an interface of the first non-active area NA1 and the bending area BA and a thickness D2b at an interface of the second non-active area NA2 and the bending area BA. Therefore, in the center portion of the bending area BA, the second planarization layer 115b may be disposed while filling an upper portion of the second link line LNK2.

Referring to FIG. 4, the bank unit 116 is disposed on the second planarization layer 115b. In the bending area BA, the bank unit 116 planarizes an upper portion of the second planarization layer 115b to planarize an entire upper portion of the bending area BA on the substrate 110. At this time, a thickness of the bank unit 116 may be larger in the bending area BA than in the first non-active area NA1 or the second non-active area NA2. Therefore, the bank unit 116 may entirely planarize the upper portion of the bending area BA by filling the upper portion of the second planarization layer 115b in the bending area BA.

When the substrate is bent to reduce an area of the bezel in the display device, it is necessary to ensure flexibility of not only the substrate, but also various insulating layers formed on the substrate and a link line formed of a metal material. In the case of the link line, when the substrate is bent, the stress is concentrated on the link line disposed on the bending area to cause a crack in the link line. When the link line is cracked, a signal is not normally transmitted so that the thin film transistor or the light emitting diode does not normally operate. Therefore, a consistent bending stress acts on the bending area of the display panel so that there is a problem in that the display panel is broken or a quality of the display panel is easily degraded.

Further, when the display device is repeatedly heated and cooled, the components of the display panel of the display device are expanded and contracted. If this process is repeated, a stress is also generated in the bending area, on the display panel, which causes the crack of the display panel PN and causes the defect of the display device due to the crack.

In the display device 100 according to the exemplary embodiment of the present disclosure, in the bending area BA, the plurality of link lines LNK is disposed to be closer to the substrate 110 in the center portion of the bending area BA than in the interface of the substrate 110 and the first non-active area NA1 or the second non-active area NA2. Accordingly, the damage of the link line due to the tensile stress during the bending may be minimized.

Specifically, in the display device 100 according to the exemplary embodiment of the present disclosure, the closer to the center portion of the bending area BA from the first non-active area NA1 in the bending area BA, the thinner the first planarization layer 115a and the closer to the second non-active area NA2 from the center portion of the bending area BA, the thicker the first planarization layer 115a disposed on the substrate 110. That is, in the bending area BA, the first planarization layer 115a is disposed to be closer to the substrate 110 in the center portion of the banding area BA than in the first non-active area NA1 or the second non-active area NA2. Therefore, the second link lines LNK2 is disposed on the first planarization layer 115a to be the closest to the substrate 110 in the center portion of the bending area BA, among the bending area BA. At this time, the neutral plane of the bending area BA is located on the substrate 110. Accordingly, in the center portion of the bending area BA, the second link line LNK2 is disposed to be close to the substrate 110 to minimize the stress due to the bending from being concentrated. In the display device 100 according to the exemplary embodiment of the present disclosure, in the bending area BA, the plurality of link lines LNK is disposed to be closer to the substrate 110 in the center portion of the bending area BA than in the interface of the substrate 110 and the first non-active area NA1 or the second non-active area NA2. By doing this, the damage of the link line due to the tensile stress during the bending may be minimized and the reliability of the display device 100 may be improved.

Further, even though it is not illustrated in FIG. 4, the substrate 110 may not include an insulating film 110c in a partial area of the bending area BA. For example, the insulating film 110c may be patterned in the bending area BA. In the bending area BA, the insulating film 110c including an inorganic material is patterned to minimize the stress caused by the bending from being concentrated.

Further, in the display device 100 according to the exemplary embodiment of the present disclosure, the crack generated in the bending area BA is minimized to improve the reliability and the lifespan of the display device 100, thereby implementing a low power display device with reduced power consumption.

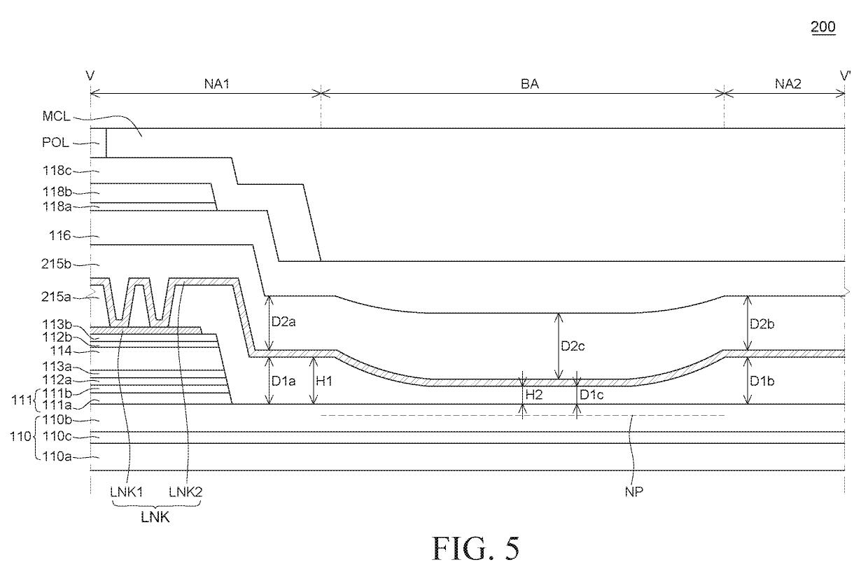

FIG. 5 is a cross-sectional view of a display device according to another exemplary embodiment of the present disclosure. The only difference between a display device 200 of FIG. 5 and the display device 100 of FIGS. 1 to 4 is a first planarization layer 215a, a second link line LNK2, and a second planarization layer 215b, but the other configuration is the same, so that a redundant description will be omitted.

Referring to FIG. 5, in the bending area BA, the first planarization layer 215a has a concave shape. For example, as seen on the cross-section, the first planarization layer 215a is formed by a concave curved surface. Therefore, the first planarization layer 215a may have a thickness which is thinner in a position of the center portion of the bending area BA than in a position close to the interface of the first non-active area NA1. At this time, the first planarization layer 215a may have a concave curved shape using a slit type mask. At this time, a steepness of a slope of a concave shape of the first planarization layer 215a may be adjusted according to a slit spacing of the mask. For example, the narrower the slit spacing of the mask, the gentler the slope and the wider the slit spacing, the steeper the slope so that a concave curved shape may be formed.

In the bending area BA, the second link line LNK2 is disposed above the first planarization layer 215a. That is, in the bending area BA, the second link line lNK2 may be disposed with a concave curved shape along the concave curved shape of the first planarization layer 215a. That is, a height H1 of the second link line LNK2 from the substrate 110 in a boundary of the first non-active area NA1 and the bending area BA may be higher than a height H2 from the substrate 110 in the center portion of the bending area BA. Therefore, a height H2 of the second link line LNK2 from the substrate 110 in the center portion of the bending area BA is lower than a height H1 from the substrate 110 in the boundary of the first non-active area NA1 and the bending area BA. Further, in the center portion of the bending area BA, the second link line LNK2 may be disposed to be the closest to the substrate 110.

In the meantime, a neutral plane NP in the bending area BA may be located in the second substrate 110b of the substrate 110. Therefore, the second link lines LNK2 may be disposed to be closer to the neutral plane of the center portion of the bending area BA than the boundary of the first non-active area NA1 or the second non-active area NA2 and the bending area BA.

In the bending area BA, the second planarization layer 215b is disposed on the second link line LNK2 with a concave curved shape. At this time, the closer to the center portion of the bending area BA from the first non-active area NA1, the larger the thickness of the second planarization layer 215b and the closer to the second non-active area NA2 from the center portion of the bending area BA, the smaller the thickness of the second planarization layer 215b. That is, a thickness D2c of the second planarization layer 215b in the center portion of the bending area BA is larger than a thickness D2a at an interface of the first non-active area NA1 and the bending area BA and a thickness D2b at an interface of the second non-active area NA2 and the bending area BA. Therefore, in the center portion of the bending area BA, the second planarization layer 215b may be disposed while filling an upper portion of the second link line LNK2.

In the display device 200 according to another exemplary embodiment of the present disclosure, in the bending area BA, the plurality of second link lines LNK2 is disposed to be closest to the substrate 110 in the center portion of the bending area BA than in the interface of the substrate 110 and the first non-active area NA1 or the second non-active area NA2. Therefore, the damage of the second link line LNK2 due to the tensile stress during the bending may be minimized.

Accordingly, in the display device 200 according to another exemplary embodiment of the present disclosure, the crack generated in the bending area is minimized to improve the reliability of the display device 200, thereby improving the lifespan to provide a low power display device with a reduced power consumption.

The exemplary embodiments of the present disclosure can also be described as follows:

According to an aspect of the present disclosure, a display device includes a substrate including an active area, a first non-active area surrounding the active area, a bending area extending from the first non-active area, and a second non-active area extending from the bending area; a first planarization layer extending from the active area to be disposed in the first non-active area, the bending area, and the second non-active area of the substrate; a plurality of link lines on the first planarization layer in the first non-active area, the bending area, and the second non-active area; and a second planarization layer on the plurality of link lines in the first non-active area, the bending area, and the second non-active area. The plurality of link lines is disposed to be closer to the substrate in a center portion of the bending area than in a boundary of the first non-active area or the second non-active area and the bending area on a cross-section.

In the bending area, the closer to the center portion of the bending area from the first non-active area, the smaller a thickness of the first planarization layer may be, and the closer to the second non-active area from the center portion of the bending area, the larger the thickness may be.

The first planarization layer may have a step shape on the cross-section.

The first planarization layer may have a concave shape on the cross-section.

In the bending area, the closer to the center portion of the bending area from the first non-active area, the larger a thickness of the second planarization layer may be, and the closer to the second non-active area from the center portion of the bending area, the smaller the thickness may be.

The display device may further include a bank unit planarizing an upper portion of the second planarization layer in the bending area. A thickness of the bank unit may be larger in the bending area than in the first non-active area or the second non-active area on the cross-section.

The substrate may include a first substrate; an insulating film on the first substrate; and a second substrate on the insulating film. A neutral plane may be located on the second substrate.

The plurality of link lines may be disposed to be closer to the neutral plane of the center portion of the bending area than in the boundary of the first non-active area or the second non-active area and the bending area.

In the bending area, a curvature of the plurality of link lines may be smaller in the center portion of the bending area than in the boundary of the first non-active area or the second non-active area and the bending area.

According to another aspect of the present disclosure, a display device includes a substrate including an active area, a first non-active area surrounding the active area, a bending area extending from the first non-active area, and a second non-active area extending from the bending area; a first planarization layer on the substrate to be thin as it is close to a center portion of the bending area from the first non-active area and to be thick as it is close to the second non-active area from the center portion of the bending area, in the bending area; a plurality of link lines on the first planarization layer in the bending area to be closest to the substrate in the center portion of the bending area, in the bending area; and a second planarization layer on the plurality of link lines in the bending area.

The first planarization layer may have a step shape on a cross-section.

The first planarization layer may have a concave shape on a cross-section.

The substrate may includes: a first substrate; an insulating film on the first substrate; and a second substrate on the insulating film. A neutral plane may be located on the second substrate.

The plurality of link lines may be disposed to be closer to the neutral plane of the center portion of the bending area than in a boundary of the first non-active area or the second non-active area and the bending area.

The closer to the center portion of the bending area from the first non-active area, the larger a thickness of the second planarization layer in the bending area may be, and the closer to the second non-active area from the center portion of the bending area, the smaller the thickness may be.

The display device may further include a bank unit on the second planarization layer in the bending area.

A thickness of the bank unit may be larger in the bending area than in the first non-active area or the second non-active area on a cross-section.

A curvature of the plurality of link lines may be smaller in the center portion of the bending area than in a boundary of the first non-active area or the second non-active area and the bending area in the bending area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area, a first non-active area surrounding the active area, a bending area extending from the first non-active area, and a second non-active area extending from the bending area;
a first planarization layer extending from the active area to be disposed in the first non-active area, the bending area, and the second non-active area of the substrate;
a plurality of link lines on the first planarization layer in the first non-active area, the bending area, and the second non-active area; and
a second planarization layer on the plurality of link lines in the first non-active area, the bending area, and the second non-active area,
wherein the plurality of link lines is disposed to be closer to the substrate in a center portion of the bending area than in a boundary of the first non-active area or the second non-active area and the bending area on a cross-section.

2. The display device according to claim 1, wherein in the bending area, the closer to the center portion of the bending area from the first non-active area, the smaller a thickness of the first planarization layer, and the closer to the second non-active area from the center portion of the bending area, the larger the thickness.

3. The display device according to claim 2, wherein the first planarization layer has a step shape on the cross-section.

4. The display device according to claim 2, wherein the first planarization layer has a concave shape on the cross-section.

5. The display device according to claim 1, wherein in the bending area, the closer to the center portion of the bending area from the first non-active area, the larger a thickness of the second planarization layer, and the closer to the second non-active area from the center portion of the bending area, the smaller the thickness.

6. The display device according to claim 5, further comprising:
a bank unit planarizing an upper portion of the second planarization layer in the bending area,
wherein a thickness of the bank unit is larger in the bending area than in the first non-active area or the second non-active area on the cross-section.

7. The display device according to claim 1, wherein the substrate includes:
a first substrate;
an insulating film on the first substrate; and
a second substrate on the insulating film,
wherein a neutral plane is located on the second substrate.

8. The display device according to claim 7, wherein the plurality of link lines is disposed to be closer to the neutral plane of the center portion of the bending area than in the boundary of the first non-active area or the second non-active area and the bending area.

9. The display device according to claim 1, wherein in the bending area, a curvature of the plurality of link lines is smaller in the center portion of the bending area than in the boundary of the first non-active area or the second non-active area and the bending area.

10. A display device, comprising:
a substrate including an active area, a first non-active area surrounding the active area, a bending area extending from the first non-active area, and a second non-active area extending from the bending area;
a first planarization layer on the substrate to be a first thickness as it is close to a center portion of the bending area from the first non-active area and to be a second thickness as it is close to the second non-active area from the center portion of the bending area, in the bending area, wherein the first thickness is smaller than the second thickness;
a plurality of link lines on the first planarization layer in the bending area to be closest to the substrate in the center portion of the bending area, in the bending area; and
a second planarization layer on the plurality of link lines in the bending area.

11. The display device according to claim 10, wherein the first planarization layer has a step shape on a cross-section.

12. The display device according to claim 10, wherein the first planarization layer has a concave shape on a cross-section.

13. The display device according to claim 10, wherein the substrate includes:
a first substrate;
an insulating film on the first substrate; and
a second substrate on the insulating film,
wherein a neutral plane is located on the second substrate.

14. The display device according to claim 13, wherein the plurality of link lines is disposed to be closer to the neutral plane of the center portion of the bending area than in a boundary of the first non-active area or the second non-active area and the bending area.

15. The display device according to claim 10, wherein the closer to the center portion of the bending area from the first non-active area, the larger a thickness of the second planarization layer in the bending area, and the closer to the second non-active area from the center portion of the bending area, the smaller the thickness.

16. The display device according to claim 15, further comprising:
a bank unit on the second planarization layer in the bending area.

17. The display device according to claim 16, wherein a thickness of the bank unit is larger in the bending area than in the first non-active area or the second non-active area on a cross-section.

18. The display device according to claim 10, wherein a curvature of the plurality of link lines is smaller in the center portion of the bending area than in a boundary of the first non-active area or the second non-active area and the bending area in the bending area.
